(19) United States
(12) Patent Application Publication
(10) Pub. No.: US 2019/0047210 A1
(43) Pub. Date: Feb. 14, 2019

(54) EMBEDDING COMPLEX OBJECTS WITH 3D PRINTING

(71) Applicant: KING ABDULLAH UNIVERSITY OF SCIENCE AND TECHNOLOGY, Thuwal (SA)

(72) Inventors: Muhammad Mustafa HUSSAIN, Austin, TX (US); Marlon Steven DIAZ CORDERO, Thuwal (SA)

(73) Assignee: KING ABDULLAH UNIVERSITY OF SCIENCE AND TECHNOLOGY, Thuwal (SA)

(21) Appl. No.: 16/079,276

(22) PCT Filed: Apr. 5, 2017
(86) PCT No.: PCT/IB2017/051966

§ 371 Date: Aug. 23, 2018

Related U.S. Application Data
(60) Provisional application No. 62/320,122, filed on Apr. 8, 2016.

(51) Int. Cl. B29C 64/118; B33Y 10/00; B33Y 80/00; B33Y 70/00; H01L 23/538; H01L 33/56; H01L 25/075; H01L 23/14; H01L 25/16

(52) U.S. Cl. CPC B29C 64/118; B33Y 10/00; B33Y 80/00; B33Y 70/00; B29K 2067/046; H01L 33/56; H01L 25/0753; H01L 23/147; H01L 25/167; H01L 23/5387

(57) ABSTRACT

A CMOS technology-compatible fabrication process for flexible CMOS electronics embedded during additive manufacturing (i.e. 3D printing). A method for such a process may include printing a first portion of a 3D structure; pausing the step of printing the 3D structure to embed the flexible silicon substrate; placing the flexible silicon substrate in a cavity of the first portion of the 3D structure to embed the flexible silicon substrate in the 3D structure; and resuming the step of printing the 3D structure to form the second portion of the 3D structure.

### CROSS-REFERENCE TO RELATED PATENT APPLICATIONS

This application claims priority and benefit from U.S. Provisional Patent Application No. 62/320,122 by Hussain et al., filed on Apr. 8, 2016 and entitled “3D Printed Flexible Objects with Embedded Solid State Electronics”, the content of which is hereby incorporated by reference in its entirety.

### FIELD OF THE DISCLOSURE

The instant disclosure relates to electronic devices. More specifically, portions of this disclosure relate to flexible electronic devices.

### BACKGROUND

Advances in semiconductor technology have driven electronic devices to new uses and resulted in the commercialization of a significant amount of new technology. Two factors that contribute to the rapid advancing of electronic devices are increased chip integration density (e.g., number of transistors per unit area) and improvements to microelectronics packaging that reduce the size of components in the device. For example, increased chip integrated density has allowed increases in processor performance and increases in memory sizes in electronic devices such as mobile phones. As another example, improved packaging techniques have allowed for manufacturing of thin components to support thin mobile devices. However, consumer electronic devices are still fixed, rigid, and inflexible devices. Such rigid devices limit the creativity of designers of electronic devices and limit the application for the electronic devices. For example, rigid-shaped cages for electronic devices are generally incompatible for integration with living beings for in vivo or in vitro applications.

Some conventional solutions for building more flexible electronic devices include replacing rigid circuit boards with flexible printed circuit board (fPCB) technology, chip-on-film packaging, and chip-in-film packaging. However, these solutions are less than ideal for fully flexible three-dimensional (3D) devices. Although conventional solutions can produce interconnections between electronic components, these solutions are not designed to build 3D complex packaging.

### SUMMARY

Three-dimensional (3D) printing technology can be used to build flexible electronic devices. 3D printing can use additive manufacturing technologies to build custom structures of nearly any shape or size, limited only by the printer. Flexible and/or fragile electronic devices fabricated on semiconductor structures can be encased within 3D printed structures to form flexible 3D printed complex objects. The mechanical flexibility introduced by 3D printed packaging techniques allows a conformal integration of the packaged components with the destination sites, including soft asymmetric substrates (e.g., tissue, skin). 3D printed packages can be manufactured to serve as sensors, actuators, wireless modules, data processing units, or the like. Such 3D printed flexible electronic devices can be used in live and freeform electronics, wearable technologies, and implantable technologies in healthcare, consumer electronics, aircraft, and automobile industries. These consumer and other electronic devices may allow the creation of three dimensional complex systems with higher throughput and lower cost compared to conventional manufacturing techniques.

According to one embodiment, an apparatus may include a flexible substrate comprising an electronic device; and/or a three-dimensional (3D) structure created by 3D printing, wherein the flexible silicon substrate is embedded in the three-dimensional (3D) structure.

According to another embodiment, a manufacturing method may include printing a three-dimensional (3D) structure using a three-dimensional (3D) printer; and/or embedding a flexible substrate comprising an electronic device in the three-dimensional (3D) structure during the printing of the three-dimensional (3D) structure such that a first portion of the 3D structure is printed prior to embedding the flexible silicon substrate and a second portion of the three-dimensional (3D) structure is printed after embedding the flexible silicon substrate.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

For a more complete understanding of the disclosed system and methods, reference is now made to the following descriptions taken in conjunction with the accompanying drawings.

FIG. 1 is a flow chart illustrating an example method for manufacturing flexible electronic devices with three-dimensional (3D) additive printing according to one embodiment of the disclosure.

FIGS. 2A-2C are perspective views of a three-dimensional (3D) structure with embedded electronic device at various stages of manufacturing according to embodiments of the disclosure.

FIG. 3 is a flow chart illustrating an example method for manufacturing flexible electronic devices with three-dimensional (3D) printing by pausing, placing, and resuming printing according to one embodiment of the disclosure.

FIGS. 4A-E are graphs showing performance of LEDs inside different 3D packaging materials according to different embodiments of the disclosure.

FIG. 5 is a graph showing performance of metal-oxide-semiconductor capacitors (MOSCAPs) before and after embedding in a three-dimensional (3D) structure according to different embodiments of the disclosure.

### DETAILED DESCRIPTION

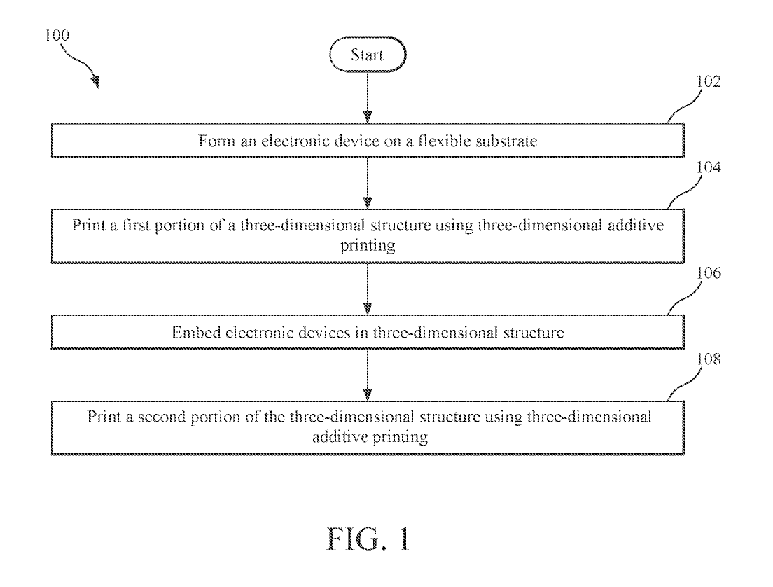

FIG. 1 is a flow chart illustrating an example method 100 for manufacturing flexible electronic devices with three-dimensional (3D) additive printing according to one embodiment of the disclosure. The method 100 may begin at block 102 with forming an electronic device on a flexible substrate, such as an optoelectronic device including light emitting diodes (LEDs) 205 on a flexible silicon substrate 203. The flexible silicon substrate may be formed by thinning a silicon substrate to a substrate of less than 50 micrometers after forming the electronic device on the substrate. One example of a process for thinning semiconductor substrate to form flexible substrates is described in U.S. patent application Ser. No. 14/238,526 filed on Apr. 2, 2014 (now issued as U.S. Pat. No. 9,520,293) and entitled “Method for Producing Mechanically Flexible Silicon Substrate,” the content of which is hereby incorporated by reference in its entirety. In some processes, the flexible substrate for embedding in the 3D structure may be provided to the printer of the 3D structure, rather than manufactured as part of the same process. The electronic devices formed at block 102 may include solid state, high-performance, ultra-large-scale integration (ULSI) density, high energy efficiency, and/or high reliability devices. The electronic devices may include, for example, one or more of metal-insulator-metal capacitors (MIMCAPs), metal-oxide-semiconductor capacitors (MOSCAPs), metal-oxide-semiconductor field effect transistors (MOSFETs), thermoelectric harvesters, fin-based field effect transistors (FinFETs), and/or sensors (such as accelerometers, temperature sensors, etc.). (MOSCAPs), (MIMCAPs), (MOSFETs), thermoelectric harvesters, (FinFETs), and sensors

Next, the method 100 continues with printing the 3D structure and embedding the flexible substrate with electronic devices into the 3D structure. At block 104, a first portion of a three-dimensional (3D) structure is printed using three-dimensional (3D) additive printing. Some example devices for performing the 3D printing include the Stratasys Objet260 Connex 1 and the MakerBot Replicator 2. In some embodiments, the 3D structure may be freeform electronics used in, for example, Internet of Everything consumer products. In some embodiments, a rigid floor may be fabricated under the location of the flexible substrate to reduce stresses being exerted on the flexible substrate without compromising the bending capabilities of the flexible substrate. Sample devices constructed with the rigid floor may show that even after 1000 bending cycles, the flexible substrates do not substantially change. Then, at block 106, the flexible substrate with electronic devices is embedded in the 3D structure. In some embodiments, embedding of the flexible substrate may be performed by a robotic arm. The robotic arm may be operated by a system controller that moves the robotic arm and operates the 3D printer. Next, at block 108, a second portion of the 3D structure is printed using 3D additive printing. In some embodiments, the second portion may complete the 3D structure, while in other embodiments another flexible substrate may be embedded after the second portion, and then a third portion used to complete the 3D structure, and so on for multiple portions (i.e., fractions) as described below.

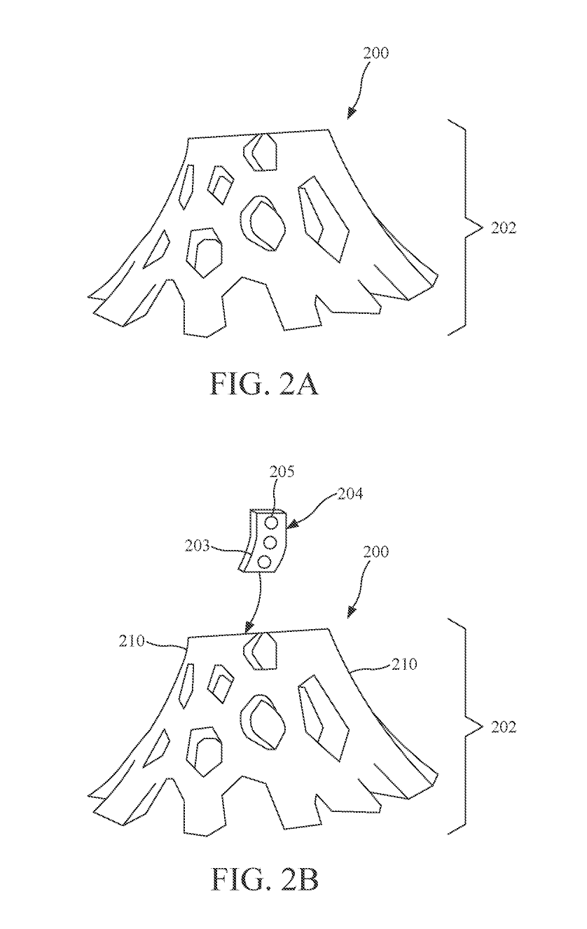

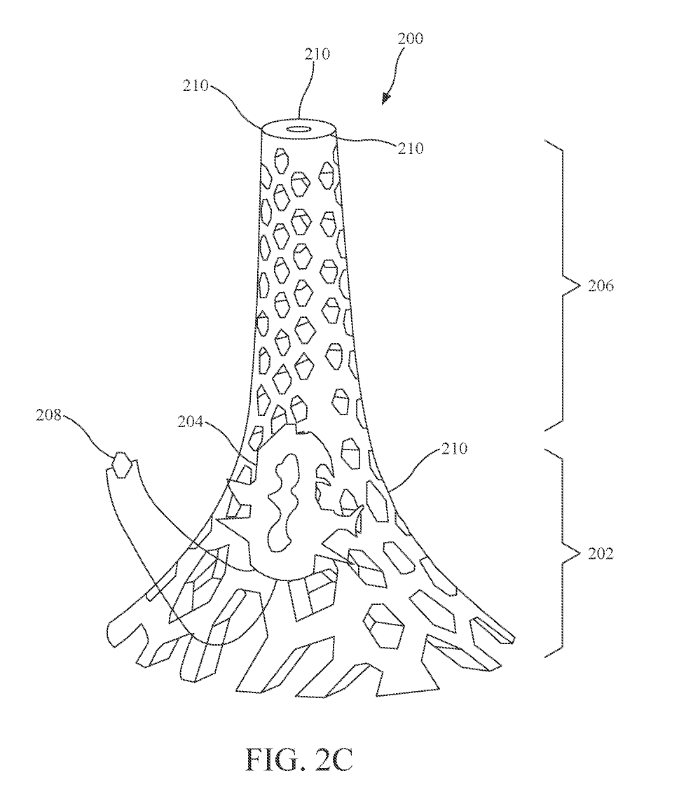

FIGS. 2A-2C are perspective views of a three-dimensional (3D) structure 200 with embedded electronic device at various stages of manufacturing according to embodiments of the disclosure. FIG. 2A illustrates the 3D structure 200 after a first portion 202 of a 3D structure is printed, such as after block 104 of FIG. 1 is performed, according to one embodiment of the disclosure. The 3D structure 200 may be formed from, for example, a thermoplastic elastomer (such as NinjaFlex®). A thermoplastic elastomer may be selected when flexibility of the 3D structure is desirable, because thermoplastic elastomers may demonstrate flexibility under bending and compressive conditions. Other materials for fabricating the 3D structure may include Polylactic acid (PLA), Polydimethylsiloxane (PDMS), or a combination of these materials. PDMS may be selected when the electronic device to be embedded is an optoelectronic device, because PDMS is an effective material for encapsulation of light emitting devices due to its intrinsic properties, such as liquid phase impermeability, high light transmittance, extreme flexibility, and stretchability. Optoelectronic devices fabricated in PDMS show no or little performance degradation in terms of mechanical flexibility.

FIG. 2B illustrates the 3D structure 200 after embedding one or more electronic devices 204 in the 3D structure, such as after block 106 of FIG. 1 is performed, according to one embodiment of the disclosure. A flexible substrate 203 may comprise the one or more electronic devices 204. In the embodiment of FIGS. 2A-C, the one or more electronic devices 204 may comprise light emitting diodes (LEDs) 205. FIG. 2C illustrates the 3D structure after a second portion 206 of the 3D structure is printed, such as after block 108 of FIG. 1 is performed, according to one embodiment of the disclosure. A power source 208 may be coupled to the electronic device to power the device. The power source may be external to the 3D structure or may be embedded in the 3D structure, such as by embedding a power source or battery in the 3D structure.

In some embodiments, the second portion 206 printed at block 108 is the remainder of the 3D structure left to print after the first portion 202 is complete. In other embodiments, the second portion printed at block 108 may be another fraction of the complete 3D structure. Additional subsequent steps may then be performed to complete the printing of the 3D structure by printing additional portions. For example, multiple electronic devices may be incorporated into a 3D structure by repeating the steps of printing and embedding. In one example, a first portion of a 3D structure may be printed, followed by embedding of a first electronic device 204 on a flexible substrate 203, then a second portion of a 3D structure may be printed, followed by embedding of a second electronic device on a flexible substrate, and then a third, and possibly final, portion of the 3D structure may be printed. In some embodiments, filaments for the 3D printer may be changed after portions of the 3D structure are printed. A complex 3D structure made of different materials may be constructed by changing the filament from one material type to another as portions of the 3D structure are printed.

In some embodiments, the packaging material does not adhere to the flexible substrate 203 embedded in the 3D structure, which may create a conformal packaging around the sample that is small enough to keep the flexible substrate in place. Because there is no adhesion between the flexible substrate and the packaging material, no thermal expansion or internal stresses are being exerted onto the flexible substrate. Thus, the maximum strain experience by the flexible substrate may be approximately:

$$ɛ = \frac{t}{2 R} ,$$

where ε is a strain value, t is the thickness of the flexible substrate, and R is a bending radius.

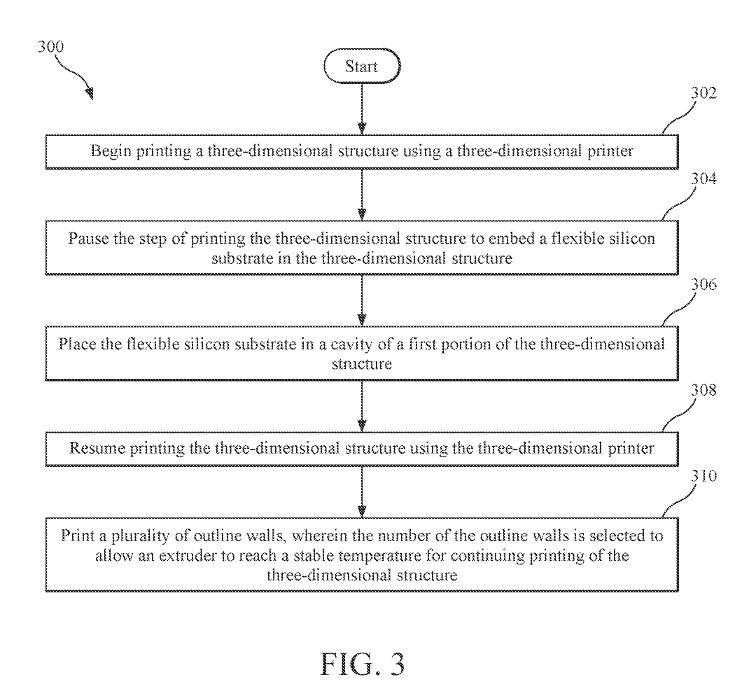

During the 3D printing, the 3D printing process may be interrupted by a process of pausing, placing, and resuming to embed the flexible substrate into the 3D structure being printed. FIG. 3 is a flow chart illustrating an example method 300 for manufacturing flexible electronic devices with three-dimensional (3D) printing by pausing, placing, and resuming printing according to one embodiment of the disclosure. The method 300 may begin at block 302 with beginning the printing of a three-dimensional (3D) structure using a three-dimensional printer, such as a 3D additive printer. At block 304, the printing may be paused to allow embedding of an electronic device, such as may be formed on a flexible silicon substrate. At block 306, the flexible silicon substrate containing one or more electronic devices may be placed in a cavity of the printed portion of the 3D structure. Then, at block 308, the printing of the 3D structure may be resumed in the 3D printer, such as by continuing additive printing.

During the pausing step of the embedding process, the cohesion between the last layer of the first portion and the first layer of the second portion after resuming the printing may not be as strong as cohesion between subsequent layers. When layers are deposited immediately subsequently, the extruder of the 3D printer may maintain a nearly constant temperature during deposition. Pausing and resuming the 3D printing process may cause the extruder temperature to change, which may result in lower cohesion between layers resulting from non-stable printing temperatures. As the extruder returns to normal temperature (i.e., stable printing temperature, e.g., 215° C.), the cohesion between layers returns to normal. In order to minimize the variation between layers after pausing and resuming the 3D printing, outline walls (e.g., 210) may be printed upon resuming the 3D printing. In some embodiments, immediately upon resuming, a plurality of outline walls 210, such as three or more, may be printed at block 310. The number of outline walls printed at block 310 may be selected to allow an extruder to reach a stable temperature for continuing printing of the 3D structure, after which additional portions of the 3D structure may be printed. The number of outline walls may be selected to allow the temperature of the extruder to stabilize before printing the inside of the 3D design. Alternatively, or additionally, at block 310, filaments may be unloaded and loaded to push out material from the head of the extruder and stabilize the temperature of the extruder before the 3D printing process resumes. In some embodiments, low thickness (<50 micrometers) of the substrate 203 may enable placement between two consecutive 3D printed layers without making any changes in the design of the 3D printed object (such as creating a cavity). Since 3D printed materials may be deposited at high temperatures (e.g., 215° C.), the materials may be highly malleable, allowing the thin film pieces (e.g., 15×15 mm and 15×4 silicon pieces) to be placed between two subsequent layers without interfering with the printing processes.

In one embodiment, support material may be used to fill empty cavities of the 3D structure while the 3D structure is being printed. More than one nozzle may be employed on such a 3D printer to improve printing speed. The method 300 may be adapted for this embodiment by pausing the printing process at a predetermined height, clearing support material to form a cavity, placing the electronic device in the cavity, and resuming the printing to cover the device. As the printing process is resumed, all nozzles may start releasing new material.

In other embodiments, single nozzle 3D printers may form the 3D structure, such as with fused deposition modeling (FDM). In FDM, melted material is extruded out of a nozzle to build 3D structures. With FDM, a single extruder deposits the packaging material and allows each layer of material to be support for the next layer of material. A catenary effect may be observed in FDM printing, wherein the effect is defined by the equation:

$$y ( x ) = acosh ( \frac{x}{a} ) ,$$

where y is the height of the catenary, a is a constant defined by a horizontal tension and the weight per unit length.

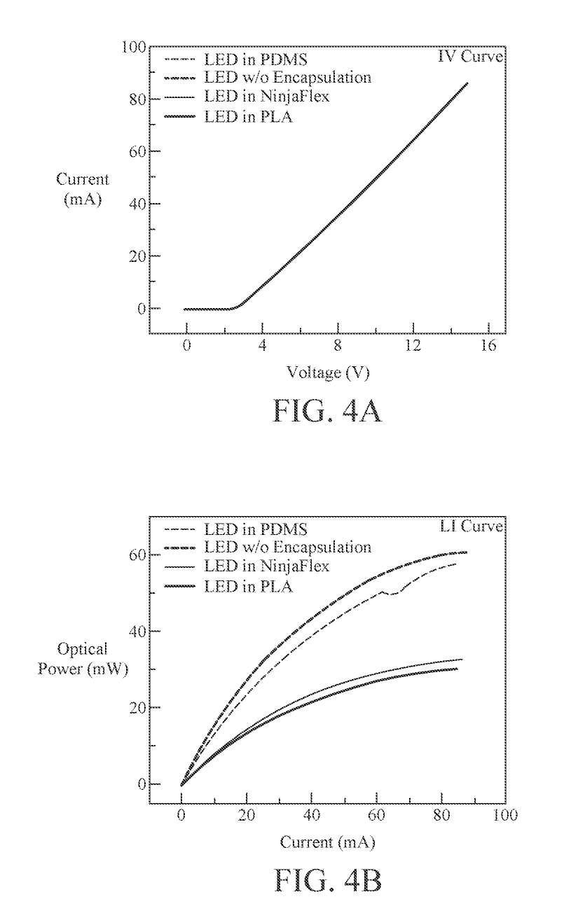

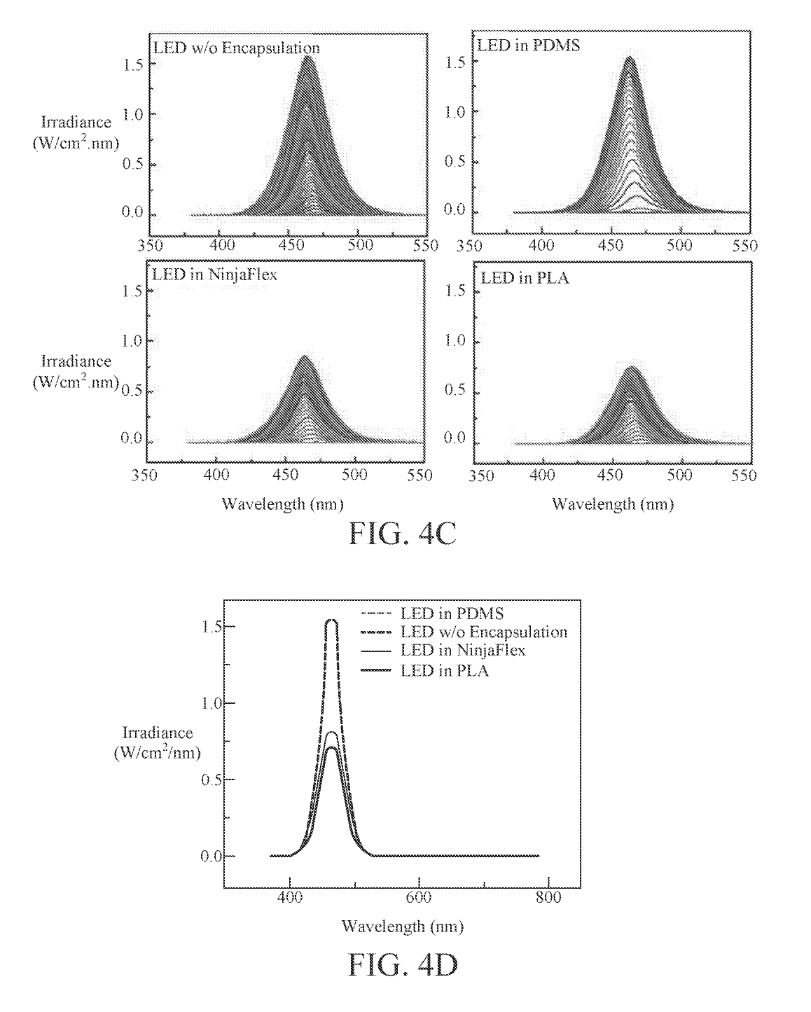

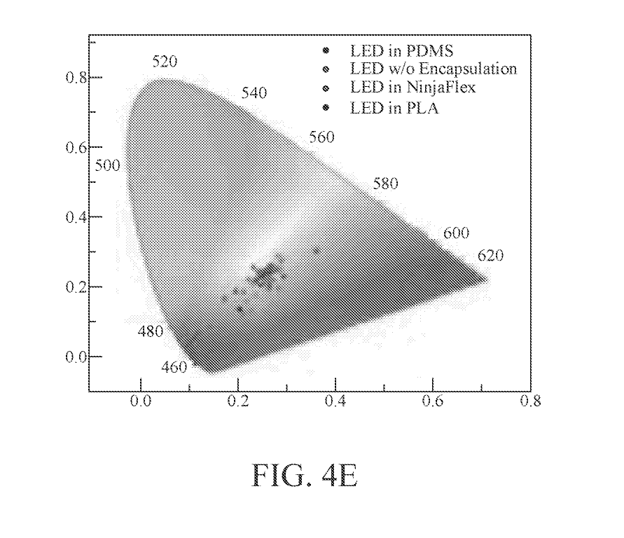

One important consideration in the 3D structure material for embedded optoelectronic devices is absorbance of the encapsulation material. The transmittance obtained for PDMS may be above 90%, whereas transmittance of NinjaFlex® and PLA encapsulation materials may be about 40% lower than PDMS. Additional characteristics of various encapsulation materials is shown in FIGS. 4A-E. FIGS. 4A-E are graphs showing performance of LEDs inside different 3D packaging materials according to different embodiments of the disclosure. FIG. 4A illustrates a current-voltage (I-V) curve of LEDs inside different packaging materials according to one embodiment of the disclosure. FIG. 4A shows there is little or no variation between curves for different encapsulation materials. FIG. 4B illustrates an optical power-current (L-I) curve of LEDs inside different packaging materials according to one embodiment of the disclosure. FIG. 4C illustrates irradiance-wavelength graphs after embedding LEDs into different materials according to embodiments of the disclosure. A decrease in optical power and irradiancy are shown in FIG. 4B and FIG. 4C, respectively, for certain packaging materials. FIG. 4D illustrates irradiance measured at 460 nanometers for different materials according to embodiments of the disclosure. FIG. 4E illustrates chromaticity measured after embedding LEDs in diverse materials. FIG. 4D and FIG. 4E show that there is little or no undesirable influence on the light quality or color being emitted through the packaging materials.

Transmittance and other characteristics of the encapsulation material may be dependent upon printing parameters. Other characteristics of the encapsulation material are also affected by printing parameters. For example, when handling soft or flexible materials, the printing speed may be reduced to approximately 10-22 millimeters per second. Other parameters for customization may include speed of printing, temperature, percentage of infill (e.g., size of hexagons filling each layer), number of solid layers at the top and bottom, and/or number of outlines. Further, the percentage of infill may determine a flexibility and stretchability of the 3D structure.

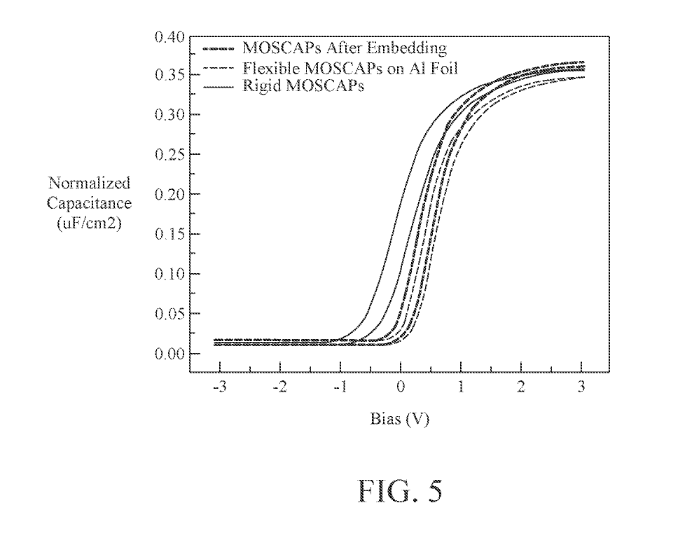

Although LEDs (205) are included as the electronic device in embodiments described above other electronic devices may be embedded in a 3D structure, such as MOSCAPs, and those other electronic devices may have performance when embedded similar to their performance when not embedded, such as shown in FIG. 5. FIG. 5 is a graph showing performance of metal-oxide-semiconductor capacitors (MOSCAPs) before and after embedding in a three-dimensional (3D) structure according to different embodiments of the disclosure.

The schematic flow chart diagrams of FIG. 1 and FIG. 3 and the other methods described above are generally set forth as a logical flow chart diagram. As such, the depicted order and labeled steps are indicative of aspects of the disclosed method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagram, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Although the present disclosure and certain representative advantages have been described in detail, it should be understood that various changes, substitutions and alterations can be made herein without departing from the spirit and scope of the disclosure as defined by the appended claims. For example, although 3D printing is described throughout the application, manufacturing methods described herein and resulting apparatuses may be produced through any additive manufacturing technique. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1. An apparatus, comprising:
a flexible substrate comprising an electronic device; and
a three-dimensional, 3D, structure created by 3D printing, wherein the flexible silicon substrate is embedded in the 3D structure.

2. The apparatus of claim 1, wherein the flexible substrate is embedded between two subsequent layers of the printed 3D structure.

3. The apparatus of claim 1, wherein the flexible substrate comprises a flexible silicon substrate.

4. The apparatus of claim 1, wherein the flexible substrate has a thickness of less than approximately 50 micrometers.

5. The apparatus of claim 1, wherein the electronic device comprises at least one of metal-oxide-semiconductor capacitors (MOSCAPs), metal-insulator-metal capacitors (MIMCAPs), metal-oxide-semiconductor field effect transistors (MOSFETs), thermoelectric harvesters, fin-based field effect transistors (FinFETs), and sensors.

6. The apparatus of claim 1, wherein the electronic device comprises optoelectronics comprising at least one light emitting diode (LED) 205.

7. The apparatus of claim 1, wherein the 3D structure comprises a thermoplastic elastomer.

8. The apparatus of claim 1, wherein the 3D structure comprises a Polylactic acid.

9. The apparatus of claim 1, wherein the 3D structure comprises Polydimethylsiloxane (PDMS) material.

10. A method, comprising:
printing a three-dimensional, 3D, structure using a 3D printer; and
embedding a flexible substrate comprising an electronic device in the 3D structure during the printing of the 3D structure such that a first portion of the 3D structure is printed prior to embedding the flexible silicon substrate and a second portion of the 3D structure is printed after embedding the flexible silicon substrate.

11. The method of claim 10, wherein the step of embedding comprises:
pausing the step of printing the 3D structure to embed the flexible silicon substrate;
placing the flexible silicon substrate in a cavity of the first portion of the 3D structure to embed the flexible silicon substrate in the 3D structure; and
resuming the step of printing the 3D structure to form the second portion of the 3D structure.

12. The method of claim 11, further comprising printing a plurality of outline walls after resuming 3D printing, wherein a quantity of the plurality of outline walls is selected to allow an extruder to reach a stable temperature for continued 3D printing of filling the outline walls.

13. The method of claim 11, further comprising reloading a filament used for 3D printing, wherein the reloading allows an extruder to reach a stable temperature for continued 3D printing.

14. The method of claim 13, wherein the step of placing the flexible silicon substrate in the cavity is performed by a robotic arm.

15. The method of claim 10, wherein the step of embedding the flexible silicon substrate comprises embedding at least one light emitting diode (LED) in the 3D structure.

16. The method of claim 10, wherein the step of printing the 3D structure comprises printing a thermoplastic elastomer.

17. The method of claim 10, wherein the step of printing the 3D structure comprises printing a Polylactic acid.

18. The method of claim 10, wherein the step of printing the 3D structure comprises printing Polydimethylsiloxane (PDMS) material.

19. The method of claim 10, wherein the step of embedding a flexible substrate comprises embedding a flexible silicon substrate.

20. The method of claim 10, further comprising manufacturing the electronic device on a substrate, and thinning the substrate to form the flexible substrate.
